(19) United States
(12) Patent Application Publication
(10) Pub. No.: US 2024/0014631 A1
(43) Pub. Date: Jan. 11, 2024

(54) MANAGING LASER SYSTEM OPTICAL CHARACTERISTICS

(71) Applicant: Analog Photonics LLC, Boston, MA (US)

(72) Inventors: Christopher Vincent Poulton, Somerville, MA (US); Matthew Byrd, Arlington, MA (US); Peter Nicholas Russo, Arlington, MA (US); Diedrik Vermeulen, Boston, MA (US)

(73) Assignee: Analog Photonics LLC, Boston, MA (US)

(21) Appl. No.: 18/347,907

(22) Filed: Jul. 6, 2023

Related U.S. Application Data
(60) Provisional application No. 63/358,574, filed on Jul. 6, 2022.

(51) Int. Cl. H01S 5/0687; H01S 5/0225; H01S 5/068; H01S 5/02

(52) U.S. Cl. CPC H01S 5/0687; H01S 5/0225; H01S 5/06817; H01S 5/021

(57) ABSTRACT

An apparatus comprises an optical cavity formed on a substrate and defining a round-trip optical path, an interface positioning at least a portion of a gain medium to provide an active portion of the round-trip optical path over which the gain medium provides sufficient gain for the optical wave to propagate around the round-trip optical path in a single mode, an output coupler coupling a portion of the optical wave out of the optical cavity from a passive portion of the round-trip optical path into a waveguide segment formed on the substrate, one or more tap couplers each diverting less than 50% of optical power from the waveguide segment, and one or more on-chip modules each receiving diverted optical power from at least one of the tap couplers and providing information associated with a laser that comprises the optical cavity and the gain medium.

### CROSS-REFERENCE TO RELATED APPLICATION(S)

This application claims priority to and the benefit of U.S. Provisional Application Ser. No. 63/358,574, entitled “MANAGING LASER SYSTEM OPTICAL CHARACTERISTICS,” filed Jul. 6, 2022, the entire disclosure of which is hereby incorporated by reference.

### STATEMENT AS TO FEDERALLY SPONSORED RESEARCH

This invention was made with government support under the following contract: DARPA Contract No. HR0011-16-C-0108. The government has certain rights in the invention.

### TECHNICAL FIELD

This disclosure relates to managing laser system optical characteristics.

### BACKGROUND

In applications such as LiDAR, it may be useful to provide a laser source that generates light at multiple wavelengths, is narrow in linewidth, and generates a linear frequency chirp.

### SUMMARY

In one aspect, in general, an apparatus comprises: an optical cavity formed on a substrate and configured to define a round-trip optical path, an interface configured to position at least a portion of a gain medium to provide active portion of the round-trip optical path over which the gain medium provides sufficient gain for the optical wave to propagate around the round-trip optical path in a single mode, an output coupler configured to couple a portion of the optical wave out of the optical cavity from a passive portion of the round-trip optical path into a waveguide segment formed on the substrate, one or more tap couplers each configured to divert less than 50% of optical power from the waveguide segment, and one or more on-chip modules each configured to receive diverted optical power from at least one of the tap couplers and configured to provide information associated with a laser that comprises the optical cavity and the gain medium.

Aspects can include one or more of the following features.

The apparatus further comprises: a tuning element configured to tune a frequency of the optical wave.

At least one of the one or more on-chip modules comprises optoelectronic feedback circuitry configured to receive a first portion of the optical wave coupled out of the optical cavity and control the tuning element based at least in part on the received first portion of the optical wave, the optoelectronic feedback circuitry comprising: a first optical splitter that splits the received first portion of the optical wave into two optical paths, a first tree of optical paths with a second optical splitter that splits into two optical paths of substantially equal optical path lengths, a second tree of optical paths with a third optical splitter that splits into two optical paths of substantially equal optical path lengths, where each optical path of the second tree is longer than each optical path of the first tree, an optical phase shifter configured to impose an approximately quarter wavelength optical path length shift on one of the two optical paths of the first tree or one of the two optical paths of the second tree, a first 2×2 optical coupler configured to combine a first of the two optical paths of the first tree and a first of the two optical paths of the second tree, and to provide two optical outputs to a first pair of photodetectors connected to provide a difference between their respective photocurrents as an in-phase electrical signal, and a second 2×2 optical coupler configured to combine a second of the two optical paths of the first tree and a second of the two optical paths of the second tree, and to provide two optical outputs to a second pair of photodetectors connected to provide a difference between their respective photocurrents as a quadrature-phase electrical signal.

The optoelectronic feedback circuitry is configured to determine an estimate of an instantaneous frequency of the first portion of the optical wave based at least in part on the in-phase electrical signal and the quadrature-phase electrical signal.

The optoelectronic feedback circuitry is configured to apply an approximately linear chirp to the frequency of the first portion of the optical wave.

The approximately linear chirp is based at least in part on the in-phase electrical signal and the quadrature-phase electrical signal.

The optoelectronic feedback circuitry is configured to estimate a performance characteristic associated with the laser.

The performance characteristic comprises a chirp bandwidth of the laser during operation of the laser.

The optoelectronic feedback circuitry is configured to estimate a performance characteristic associated with the laser.

The performance characteristic is based at least in part on phase noise of the laser during operation of the laser.

The optoelectronic feedback circuitry is further configured to reduce low-frequency signals associated with the phase noise of the laser during operation of the laser.

The second tree includes an optical path length delay element on an optical path coupled to an input of the third optical splitter.

The second tree includes an optical path length delay element on each optical path coupled outputs of the third optical splitter.

At least one of the first optical splitter, the second optical splitter, the third optical splitter, the first 2×2 optical coupler, or the second 2×2 optical coupler comprises a directional coupler.

At least one of (1) the first pair of photodetectors or (2) the second pair of photodetectors are configured as a balanced detector.

A first on-chip module of the one or more on-chip modules comprises optoelectronic circuitry configured to generate, from at least a portion of the diverted optical power, a phase change signal encoding a change in phase of the portion of the diverted optical power as a function of time.

A first on-chip module of the one or more on-chip modules comprises optoelectronic circuitry configured to generate, from at least a portion of the diverted optical power, a wavelength signal encoding a wavelength of the portion of the diverted optical power as a function of time.

A second on-chip module of the one or more on-chip modules comprises optoelectronic circuitry configured to generate, from at least a portion of the diverted optical power, a phase change signal encoding a change in phase of the portion of the diverted optical power as a function of time.

The apparatus further comprises: control circuitry configured to adjust the tuning element based at least in part on one or more of the wavelength signal or the phase change signal.

The optoelectronic circuitry of the first on-chip module comprises: an optical splitter that splits a first portion of the optical wave coupled out of the optical cavity into at least two optical paths according to a splitting ratio that is dependent upon the wavelength of the portion of the diverted optical power, and at least one photodetector coupled to each of at least two of the optical paths of the optical splitter.

The optical splitter is configured to split the first portion of the optical wave into exactly two optical paths.

The control circuitry is further configured to estimate the wavelength of the portion of the diverted optical power based at least in part on determining a difference between optical power in each of the optical paths of the optical splitter divided by a sum of the optical power in each of the optical paths of the optical splitter.

The optical splitter comprises a directional coupler.

The optoelectronic circuitry of the second on-chip module comprises a path-length mismatched Mach-Zehnder interferometer.

The path-length mismatched Mach-Zehnder interferometer comprises an In-phase and Quadrature-phase (IQ) detector at an output of the path-length mismatched Mach-Zehnder interferometer configured to provide an in-phase electrical signal and a quadrature-phase electrical signal.

The control circuitry is configured to estimate a magnitude of a performance characteristic associated with the laser based at least in part on the phase change signal.

Estimating the performance characteristic comprises calculating a magnitude of a sum of a plurality of phasors at each of a plurality of estimates of instantaneous frequency of the optical wave at different times.

Estimating the performance characteristic comprises calculating a Fourier transform of the phase change signal and determining magnitudes of one or more tones in the Fourier transform.

The apparatus further comprises: a chirp actuator configured to apply a chirp to a frequency of the optical wave, and a waveform generator configured to drive the chirp actuator according to a waveform generated by the waveform generator.

The control circuitry is further configured to provide a phase control signal based at least in part on the phase change signal to the waveform generator throughout at least a portion of a duration of the generation of the waveform.

The control circuitry is configured to estimate a loss due to phase noise based at least in part on the phase change signal.

The control circuitry is configured to remove low-frequency phase noise from a calculation of phase noise for the estimated loss due to phase noise.

The control circuitry is configured to estimate a total bandwidth excursion of the laser during at least a portion of a duration of the generation of the waveform.

The control circuitry is configured to use one or both of the wavelength signal or the phase change signal to calibrate the laser.

The control circuitry is configured to use one or both of the wavelength signal or the phase change signal to update an existing calibration of the laser.

The control circuitry is configured to use one or both of the wavelength signal or the phase change signal to optimize a local operating point of the laser.

The control circuitry is configured to use one or both of the wavelength signal and the phase change signal to identify a change in performance of the laser while the laser is operating.

The apparatus further comprises: a coherent receiver configured to spatially overlap (1) a received optical wave derived from the optical wave propagating around the round-trip optical path in the single mode with (2) a local oscillator optical wave having a substantially identical mode as the received optical wave.

The gain medium comprises a semiconductor laser diode medium.

The substrate comprises a silicon substrate of a silicon photonic integrated circuit, and the one or more on-chip modules are formed on the silicon photonic integrated circuit.

The gain medium is formed on a gain medium substrate other than the silicon substrate.

The gain medium substrate comprises a III-V semiconductor material.

In another aspect, in general, a method for calibrating a wavelength of an optical wave output from a laser comprises: characterizing a response of the wavelength to one or more actuators in the laser, storing information associated with a model of the characterized response, operating the laser at one or more operating points by modifying at least one of the one or more actuators in the laser, for at least a first of the operating points, measuring at least one of: a linewidth, a chirp bandwidth, or the wavelength around the first of the operating points, and performing a fine-adjustment of at least one of the actuators based at least in part on one or more of the measurements.

Aspects can include one or more of the following features.

Characterizing the response comprises searching for two or more sets of parameters associated with the actuators that generate a substantially similar wavelength of the laser.

Characterizing the response comprises processing an electronic feedback signal from a circuit on a photonic integrated circuit that comprises the laser.

The method further comprises: measuring, for at least one of the operating points, an output power of the optical wave.

In another aspect, in general, a method for managing an operating point associated with a laser comprises: monitoring a wavelength of an optical wave output from the laser during operation over a duration of time, monitoring a change in phase of the optical wave during operation over the duration of time, and modifying one or more actuators associated with the laser in response to at least one of (1) the monitored wavelength or (2) the monitored change in phase.

Aspects can include one or more of the following features.

The method further comprises: calculating phase noise based on the monitored change in phase.

Monitoring the change in phase is performed while the laser is performing a frequency chirp.

The method further comprises: monitoring a bandwidth associated with the frequency chirp.

The method further comprises: monitoring an output power of the optical wave over the duration of time.

The method further comprises: modifying at least one of the actuators to result in a predetermined wavelength of the optical wave.

The operating point is constrained by at least one of a determined phase noise or a determined chirp bandwidth.

The operating point is constrained by a determined phase noise.

The operating point is constrained by at least one of a determined wavelength or a determined chirp bandwidth.

The operating point is constrained by a determined chirp bandwidth.

The operating point is constrained by at least one of a determined wavelength or a determined phase noise.

The operating point is constrained by a determined output power.

The operating point is constrained by a predetermined wavelength, determined phase noise, or determined chirp bandwidth.

The operating point is constrained by a predetermined phase noise.

In another aspect, in general, a method for managing a laser comprises: receiving, over a duration of time, one or more sets of electrical signals comprises an in-phase electrical signal and a quadrature-phase electrical signal from one or more photodetectors coupled to an interferometer that receives a portion of an optical wave output from the laser, generating digital representations of the in-phase electrical signal and the quadrature-phase electrical signal, and controlling a frequency of the optical wave based at least in part on at least one instantaneous frequency estimate calculated from the digital representations.

Aspects can include one or more of the following features.

The method further comprises: calculating the instantaneous frequency estimate based at least in part on estimating a derivative of a phase calculated from the digital representations.

The method further comprises: calculating the derivative of the phase based at least in part on a phase difference between adjacent samples of the digital representations.

Calculating the phase difference comprises calculating respective phases each proportional to an arctangent of a ratio of the quadrature-phase electrical signal to the in-phase electrical signal at each of a plurality of samples of the digital representations, and calculating differences between respective phases.

Estimating the instantaneous frequency comprises wrapping the difference between the respective phases to a value within −pi to pi.

Calculating the phase difference comprises calculating an arctangent of a product of a complex-valued signal comprising the digital representations at a first sample and a complex conjugate of the complex-valued signal at a second sample adjacent to the first sample.

The method further comprises: compressing instantaneous frequency estimate in storage size.

The method further comprises: filtering the instantaneous frequency estimate.

The filtering is configured to use a zero-phase filter or a lowpass filter.

The method further comprises: representing the instantaneous frequency estimate as a model-based fit of the instantaneous frequency estimate.

The model-based fit comprises a polynomial fit.

Controlling the frequency of the optical wave comprises controlling a rate of change of the frequency.

Controlling the rate of change of the frequency comprises generating a substantially linear rate of change of the frequency over each of a plurality of time periods.

In another aspect, in general, an apparatus for generating an actuation signal to apply an approximately linear chirp to a frequency of a portion of an optical wave output from a laser comprises: a digital waveform synthesizer configured to generate a digital chirp rate signal, a digital-to-analog converter configured to generate an analog signal corresponding to the digital chirp rate signal, and an analog integrator configured to integrate the analog signal to provide the actuation signal.

Aspects can include one or more of the following features.

The analog integrator is configured to receive a reset signal that resets the analog integrator to a predetermined value.

The digital waveform synthesizer is configured to generate the reset signal prior to generating the digital chirp rate signal.

The digital waveform synthesizer is configured to generate the digital chirp rate signal based on a data-compressed signal.

The data-compressed signal is based at least in part on the instantaneous frequency estimate.

The data-compressed signal comprises coefficients of a polynomial.

The polynomial comprises a polynomial fit of the instantaneous frequency estimate.

The digital chirp rate signal is based at least in part on an instantaneous frequency estimate calculated from an in-phase signal and a quadrature-phase signal coherently detected from the optical wave.

The digital waveform synthesizer is configured to generate the digital chirp rate signal based at least in part on values representing a non-linear fit of at least one instantaneous frequency estimate calculated from one or more signals coherently detected from the optical wave.

The values representing the non-linear fit comprise coefficients of a polynomial fit.

The values representing the non-linear fit comprise an initial value and an exponential decay constant of a decaying exponential fit.

In another aspect, in general, a method for controlling a laser comprises: generating one or more signals from a coherent detector coupled to an interferometer feeding a portion of an optical wave output from the laser into the coherent detector, generating digital representations of the one or more signals, generating a digital control signal based on values associated with an instantaneous frequency estimate calculated from the digital representations, and controlling a frequency of the optical wave based at least in part on an analog signal generated from the digital control signal.

Aspects can include one or more of the following features.

The values associated with the instantaneous frequency estimate represent a non-linear fit of the instantaneous frequency estimate.

The method further comprises generating the values associated with the instantaneous frequency estimate based at least in part on filtering the instantaneous frequency estimate to reduce higher frequencies relative to lower frequencies.

The method further comprises receiving a reset signal that resets the analog integrator to a predetermined value.

The method further comprises generating the reset signal prior to generating the digital chirp rate signal.

The method further comprises the digital chirp rate signal based on a data-compressed signal.

The data-compressed signal is based at least in part on the instantaneous frequency estimate.

The data-compressed signal comprises coefficients of a polynomial.

The polynomial comprises a polynomial fit of the instantaneous frequency estimate.

Aspects can have one or more of the following advantages.

Techniques described herein can be used to implement an apparatus for monitoring in-situ characteristics associated with an operating point of a wavelength tunable laser. Achieving the goals of generating light at multiple wavelengths, with a narrow linewidth, and generating a linear frequency chirp can be accomplished, for example, using tunable elements that change the round-trip optical path length defined by the laser cavities, which may need to be calibrated to select operating points. The optical wave that is provided by a laser typically has as narrow linewidth and has a peak wavelength that falls in a particular range (e.g., between about 100 nm to about 1 mm, or some subrange thereof), also referred to herein as simply “light.”

Other features and advantages will become apparent from the following description, and from the figures and claims.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a schematic diagram of an example laser system.

FIG. 2 is a schematic diagram of an example wavelength monitor.

FIGS. 3A-C are schematic diagrams of example MZI phase change monitors with IQ detection.

FIG. 3D is a schematic diagram of an example MZI phase change monitor without IQ detection.

FIGS. 4A and 4B are plots of prophetic examples of wavelength and phase noise, respectively.

FIGS. 4C and 4D are plots of prophetic examples of wavelength and phase noise, respectively.

FIG. 5 is a schematic diagram of an example laser system.

FIG. 6A-D are plots showing prophetic example signals at different parts of the example laser system of FIG. 5.

FIG. 7 is a schematic diagram of an example LiDAR system with a coherent receiver.

### DETAILED DESCRIPTION

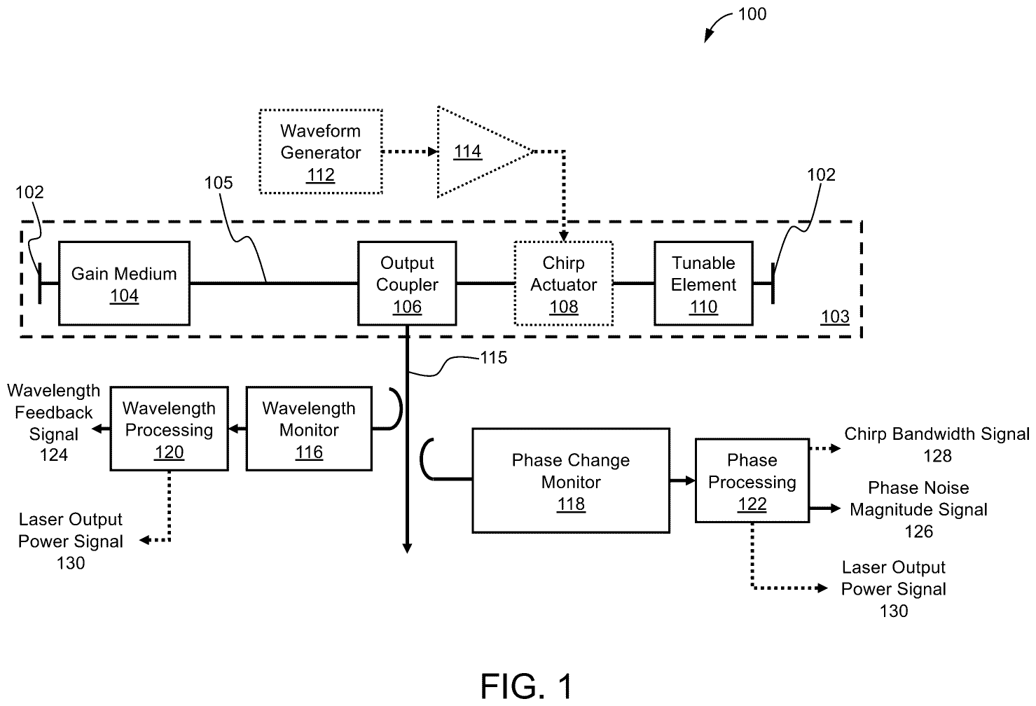

FIG. 1 shows an example laser system 100 with cavity reflectors 102 on either end forming an optical cavity 103 around a gain medium 104, an output coupler 106, an (optional) chirp actuator 108, and a tunable element 110. A waveform generator 112, in conjunction with an amplifier 114, can be used to provide an input signal to the chirp actuator 108. In some implementations that are integrated onto a photonic chip, for example, the path of the optical wave within the optical cavity 103 can be defined by one or more waveguides 105 coupling the optical elements within the optical cavity 103. In this example, the tunable element 110 is inside the optical cavity 103 and provides a tunable optical path length (e.g., by changing the index of refraction of at least a portion of the tunable element). Alternatively, the tunable element 110 could be a mechanical element (e.g., a piezoelectric element) attached to at least one of the cavity reflectors 102 for changing the round-trip optical path length. Or, the tunable element 110 could be configured to be adjustable to tune another characteristic of the laser system 100 other than (or in addition to) optical path length (e.g., an element receiving external injection of light at a different wavelength, an element introducing time dependence in the loss and/or gain of the laser system 100, an element for tuning a spatial mode of the light circulating in the optical cavity 103, and/or an element introducing optical nonlinearity, such as a Kerr frequency comb configured for selection of frequencies/wavelengths).

When the gain medium 104 is pumped above a lasing threshold, which depends on the round-trip loss within the optical cavity 103 (including output coupling loss), the optical cavity 103 (also called a “laser cavity”) lases and can be referred to as the “laser” of the laser system 100. While this example shows a linear optical cavity (or standing-wave optical cavity) that defines a round-trip path of a circulating optical wave with overlapping forward and reverse propagation directions reflected between the cavity reflectors 102 (e.g., grating reflectors), in other examples the optical cavity may be arranged as a ring cavity in which the circulating optical wave does not necessarily include any overlapping portions. In both cases, the path over which the optical wave circulates can be defined by one or more waveguides within a substrate of an integrated photonics platform on which the laser system 100 is formed (e.g., a silicon photonic integrated circuit, such as a silicon-on-insulator or other silicon photonics platform). There are a variety of ways in which the gain medium 104 can be integrated within such an integrated photonics platform. In some implementations, the gain medium 104 is provided using a different kind of material (e.g., a III-V semiconductor material) from the material on which other portions of the optical cavity 103 is formed (e.g., silicon), which is sometimes referred to as a hybrid laser system. The portion of round-trip optical path of the circulating optical wave that propagates through the gain medium can be referred to as the “active” portion, and the remaining portion of the round-trip optical path that propagates through other optical elements can be referred to as the “passive” portion. In some cases, the gain medium is formed on a separate photonics chip (the “active chip”) and embedded or otherwise coupled (e.g., using flip-chip integration) onto the other photonics chip (the “passive chip”) of the laser system 100. Such a laser with separate active and passive portions, and potentially other optical elements within the passive portion, can be more complex and difficult to operate than other kinds of lasers. For example, the performance of the laser may change over time and/or in different environmental conditions, which may call for in-situ monitoring by on-chip modules within the laser system 100 to adapt the laser operating point to these changes.

Referring again to FIG. 1, the output coupler 106 couples out a portion of the optical wave circulating within the optical cavity 103 for use as the main optical signal emitted from the laser system 100. For example, a waveguide segment 115 can be connected to an output port of the output coupler and to tap couplers of any number of on-chip modules. For example, the inclusion of a wavelength monitor 116, and a phase change monitor 118 coupled to the laser allows a laser controller (not shown) to monitor the response of the laser to its actuators and any changes in this response over time. Light may be directed into the wavelength monitor 116 and the phase change monitor, for example, by using a directional coupler as a tap coupler. One or more signals from the wavelength monitor 116 may undergo wavelength processing 120, and similarly, one or more signals from the phase change monitor 118 may undergo phase processing 122. Changes in the laser's operating point can be identified, for example, by monitoring one or more of: (1) changes in a wavelength feedback signal 124, (2) changes in a phase noise magnitude signal 126 from the laser, and (3) in the case of a chirp-able laser, changes in a chirp bandwidth signal 128 from the laser for a particular chirp drive signal. In some instantiations of an optical/electronic (or “optoelectronic”) circuit that includes the wavelength monitor 116 circuit and the phase change monitor 118 circuit (e.g., based on a delayed Mach-Zehnder Interferometer (MZI) circuit), a laser output power signal 130 may also be derived from the same optical/electronic circuit. In some implementations, the laser and the optoelectronic circuit are integrated together on the same photonic integrated circuit (e.g., a silicon photonic integrated circuit).

In some examples, the laser system 100 may be used in applications such as coherent LiDAR or coherent optical communication. For example, the laser system 100 may generate one or more optical waves that can then be detected with a coherent receiver (e.g., an IQ receiver or a balanced detector, not shown). Within the coherent receiver there are two optical waves that are coherently mixed together. One of the optical waves is a local oscillator (LO), and the other optical wave is received signal (RX) such as a portion of the optical wave from the laser system 100 that is scattered back in a LiDAR application. In order to be coherently mixed, the LO and RX may be in substantially the same mode. A particular mode of the optical wave corresponds to a particular spatial mode and a particular temporal mode. The spatial mode may have a particular intensity distribution over a transverse plane that is perpendicular to the propagation axis of the optical wave. The temporal mode may depend on the basis that is used. For example, a particular temporal mode may be based on a particular longitudinal mode (with a particular wavelength) that is lasing within the laser system in continuous wave operation, or may be based on a particular temporal envelope that is lasing within the laser system in pulsed operation (e.g., in a mode locked laser). Therefore, the laser system 100 may be configured and calibrated to generate a single mode output to be used in such a coherent receiver to provide both the LO optical wave and a transmitted optical wave that will be transmitted as a transmit signal (TX) in a LiDAR or communication application and subsequently received as the RX optical wave. If the laser system 100 generates multi-mode light, then the additional modes may not be useful and may be considered a loss term in some examples. Furthermore, additional modes can actually increase the noise of the coherent receiver since it may increase the shot noise without producing a signal. In some examples, the on-chip modules (e.g., the phase change monitor 118 and the wavelength monitor 116) monitor the status of the optical cavity 103 and the (desired single mode) output. If the laser system 100 is in multi-mode operation, it can produce unwanted outputs in the laser modules since multiple statuses are being measured simultaneously, which the modules may not be able to disambiguate.

A laser controller can be implemented using any of a variety of circuitry, including a general-purpose computer, an application specific integrated circuit, or other digital and/or analog circuitry. The laser control can use the wavelength feedback signal, the chirp bandwidth, the phase noise magnitude, and/or the laser power to control various laser characteristics that affect the operating point. For example, the characteristics can include pumping of the gain medium, an optical path length through the tunable element, and/or a drive signal provided by a waveform generator (if a chirp actuator is present). By monitoring the wavelength and the phase noise of the laser, a laser controller is directly measuring quantities that can be used to improve or optimize the performance of the laser at a particular operating point. This allows self-calibration at the factory, upon bootup, periodically in the field, and/or continuously in the field. This also allows in-the-field monitoring to notify other systems/sub-systems about the laser's health and performance.

One example instantiation of a wavelength monitor uses a wavelength-dependent splitter (such as a directional coupler) to split light into two different paths.

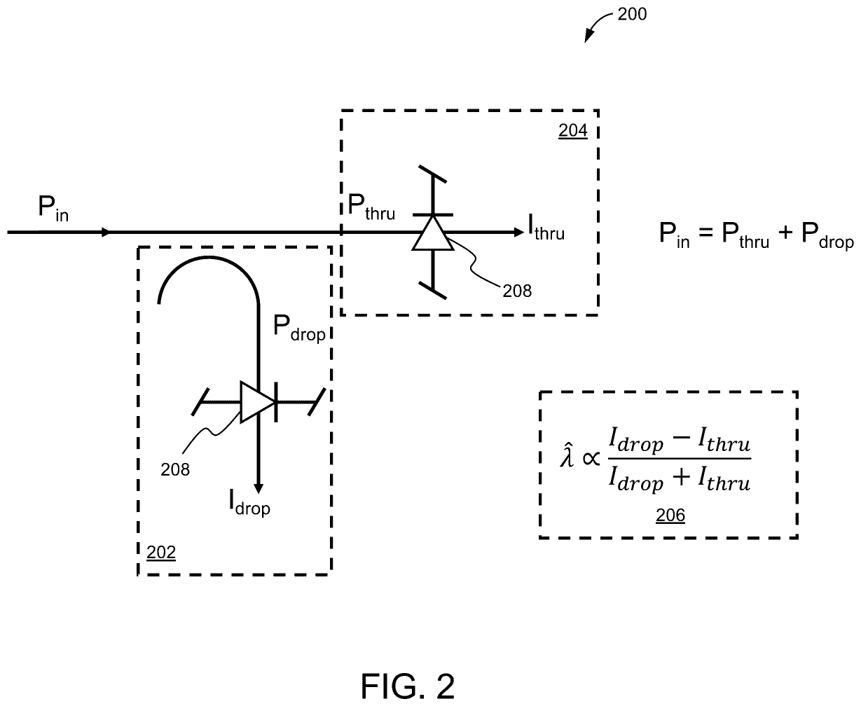

FIG. 2 shows an example directional coupler 200, longer wavelengths couple more strongly into a drop port 202 than a thru port 204. Because of this effect, a signal that is roughly proportional to the wavelength of light may be calculated by evaluating the relative imbalance of light in the thru port 204 and the drop port 202, as in an example wavelength estimate calculation 206, where the current I detected by photodetectors 208 (e.g., photodiodes) is proportional to the power P of the detected light.

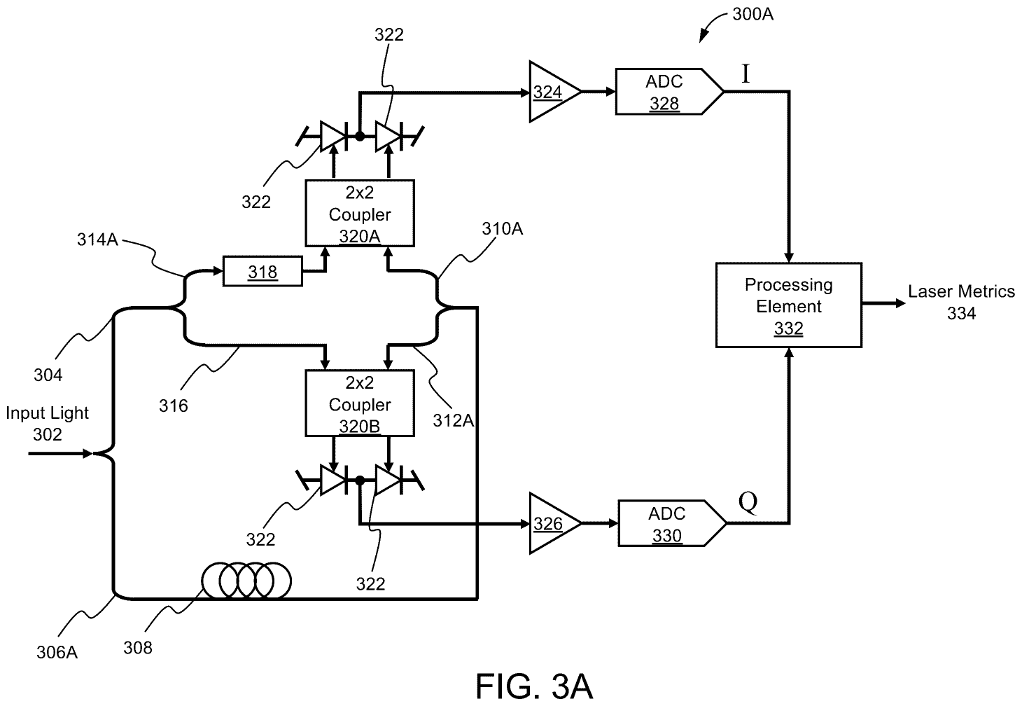

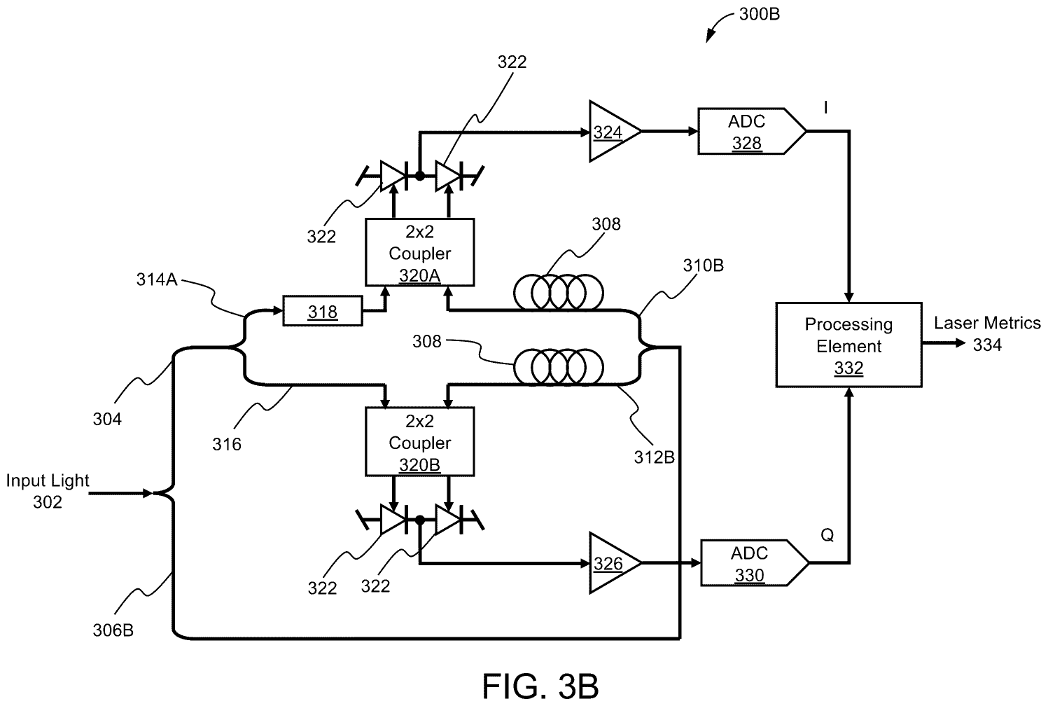

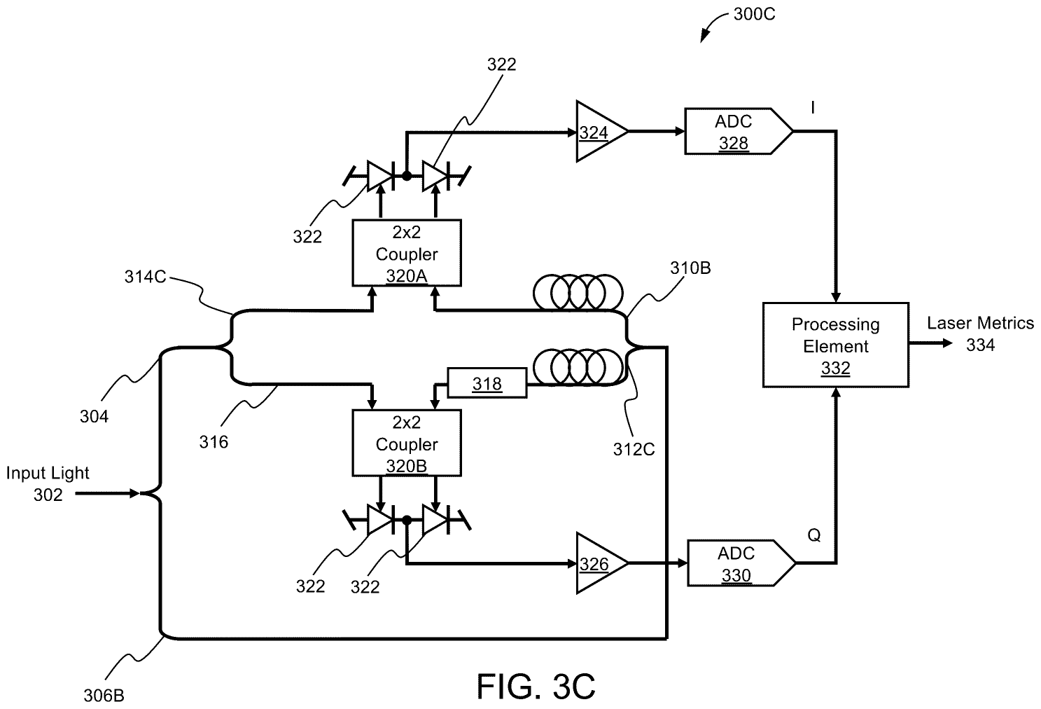

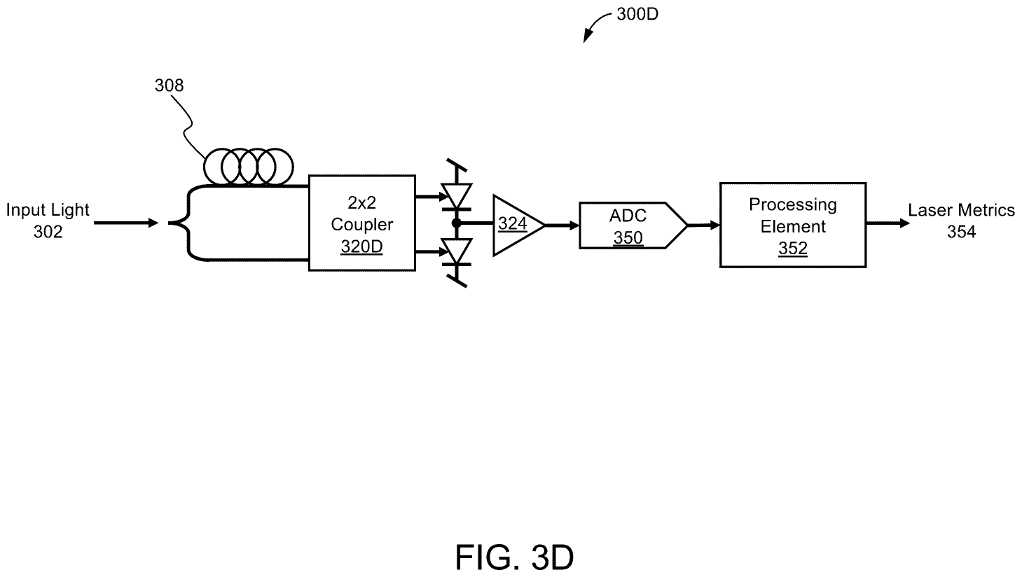

FIGS. 3A-C show various examples of different optoelectronic circuits, each configured as a phase-change monitor and comprising a path-length mismatched delayed Mach-Zehnder interferometer feeding into an IQ detector, which is amplified, digitized by analog-to-digital converters (ADCs), and then processed.

For the example phase-change monitor 300D shown in FIG. 3D, instead of using IQ detection circuitry, the in-phase and quadrature-phase components of the phasor may be calculated using a technique, such as a Hilbert transform.

FIG. 3A shows an example phase-change monitor 300A. Input light 302 is split into a first optical path 304 and a second optical path 306A. The second optical path 306A comprises a delay element 308, and splits into a third optical path 310A and a fourth optical path 312A. The first optical path 304 splits into a fifth optical path 314A and a sixth optical path 316. The fifth optical path 314A comprises a +90° phase shifting element 318. The fifth optical path 314A and the third optical path 310A are optically coupled to inputs of a first 2×2 coupler 320A, while the sixth optical path 316 and the fourth optical path 312A are optically coupled to inputs of a second 2×2 coupler 320B. The two outputs of the first 2×2 coupler 320A are optically coupled to two photodiodes 322, which are electrically connected to each other to provide a difference between their respective photocurrents as an in-phase electrical signal that is then sent to a first amplifier 324. The two outputs of the second 2×2 coupler 320B are optically coupled to two photodiodes 322, which are electrically connected to each other to provide a difference between their respective photocurrents as a quadrature-phase electrical signal that is then sent to a second amplifier 326. The first amplifier 324 is electrically connected to a first ADC 328, while the second amplifier 326 is electrically connected to a second ADC 330. Each of the ADCs are electrically connected to a processing element 332, which outputs laser metrics 334.

FIG. 3B shows an example phase-change monitor 300B. Input light 302 is split into a first optical path 304 and a second optical path 306B. The second optical path 306B splits into a third optical path 310B and a fourth optical path 312B, each comprising a delay element 308. The first optical path 304 splits into a fifth optical path 314A and a sixth optical path 316. The fifth optical path 314A comprises a +90° phase shifting element 318. The fifth optical path 314A and the third optical path 310B are optically coupled to inputs of a first 2×2 coupler 320A, while the sixth optical path 316 and the fourth optical path 312B are optically coupled to inputs of a second 2×2 coupler 320B. The two outputs of the first 2×2 coupler 320A are optically coupled to two photodiodes 322, which are electrically connected to each other to provide a difference between their respective photocurrents as an in-phase electrical signal that is then sent to a first amplifier 324. The two outputs of the second 2×2 coupler 320B are optically coupled to two photodiodes 322, which are electrically connected to each other to provide a difference between their respective photocurrents as a quadrature-phase electrical signal that is then sent to a second amplifier 326. The first amplifier 324 is electrically connected to a first ADC 328, while the second amplifier 326 is electrically connected to a second ADC 330. Each of the ADCs are electrically connected to a processing element 332, which outputs laser metrics 334.

FIG. 3C shows an example phase-change monitor 300C. Input light 302 is split into a first optical path 304 and a second optical path 306B. The second optical path 306B splits into a third optical path 310B and a fourth optical path 312C, each comprising a delay element 308. The fourth optical path 312C further comprises a +90° phase shifting element 318. The first optical path 304 splits into a fifth optical path 314C and a sixth optical path 316. The fifth optical path 314C and the third optical path 310B are optically coupled to inputs of a first 2×2 coupler 320A, while the sixth optical path 316 and the fourth optical path 312C are optically coupled to inputs of a second 2×2 coupler 320B. The two outputs of the first 2×2 coupler 320A are optically coupled to two photodiodes 322, which are electrically connected to each other to provide a difference between their respective photocurrents as an in-phase electrical signal that is then sent to a first amplifier 324. The two outputs of the second 2×2 coupler 320B are optically coupled to two photodiodes 322, which are electrically connected to each other to provide a difference between their respective photocurrents as a quadrature-phase electrical signal that is then sent to a second amplifier 326. The first amplifier 324 is electrically connected to a first ADC 328, while the second amplifier 326 is electrically connected to a second ADC 330. Each of the ADCs are electrically connected to a processing element 332, which outputs laser metrics 334.

FIG. 3D shows an example phase-change monitor 300D where the in-phase and quadrature-phase components of the phasor may be calculated using a technique, such as a Hilbert transform. In this example, the and the angle of the resulting components can be evaluated to calculate a phase using a digital representation from the ADC 350 processed by processing element 352 to compute laser metrics 354.

The optical paths in the interferometer (e.g., FIGS. 3A-C) can be implemented, for example, with waveguides in a photonic integrated circuit. In the example instantiations shown in FIGS. 3A-C, the phase difference between the undelayed and delayed arms of the phase change monitor can be evaluated by calculating the angle of the phasor constructed by using the in-phase (I) and quadrature-phase (Q) components of the IQ detector. For an (unlrealistic) “noiseless” laser with no phase noise (and no environmental noise), the phase difference between these two arms will be constant and is simply a function of the path difference between these two branches and the wavelength of the light. A realistic laser exhibits phase noise, and the laser will exhibit a random phase walk as a function of time. This random phase walk will cause a time-varying signal out of the phase change monitor.

Evaluating the magnitude of the laser's phase walk can provide an indication of (a) whether the laser is single mode or mode-hopping, and (b) the linewidth of the laser in the current operating state. The magnitude of the laser's phase walk can be calculated in a number of ways, including calculating the standard deviation of the phasor angle, although in some examples, care must be taken to properly compensate for wrapping of the measured phase around 2π boundaries. The equation below provides another method for calculating the magnitude of the phase noise, which bypasses the issue of phase wrapping while providing a measure that is directly proportional to the sensitivity reduction caused by the phase noise.

$$Loss Due to Phase Noise = \frac{{\vert {\sum }_{i = 0}^{N - 1} x ( i ) \vert}^{2}}{{\sum }_{i = 0}^{N - 1} {\vert x ( i ) \vert}^{2}}$$

where x(i) is the phasor at the i^{th} ADC sample.

In the case where the wavelength tunable laser includes a chirp actuator that is able to change the frequency of the laser output as a function of time based on a drive waveform (e.g., in some cases a linear change in frequency as a function of time, also called a linear frequency chirp), it is sometimes useful to drive a probe waveform into an input of the chirp actuator to measure (a) the phase noise while chirping, and (b) the total bandwidth excursion of the laser during the chirp. Phase noise can be measured while chirping by removing low frequency phase noise components, just the expected frequency associated with the laser chirp, or any constant phase change that comes about from a linear frequency chirp. Removing the constant phase change component provides a combined measure of the random phase noise of the laser and how linear the laser's chirp is. In the case where the low frequency phase noise terms are eliminated, the laser controller can get a measure for the achievable loss in a laser chirp if an appropriate drive waveform is discovered (without expending the time to discover that drive waveform). The equation above may be modified to discard loss effects due to “clutter” phase noise terms, such as low frequency drift in phase as may be caused by an improperly shaped drive waveform.

$$Filtered Loss Due to Phase Noise = \frac{{\vert {\sum }_{i = 0}^{N - 1} x ( i ) {e}^{- j ϕ ( i )} \vert}^{2}}{{\sum }_{i = 0}^{N - 1} {\vert x ( i ) \vert}^{2}}$$

where ϕ is a function describing the clutter phase as a function of time and j is the square root of −1. ϕ can be derived by lowpass filtering the phase of x among other methods.

It may also be useful to evaluate the total bandwidth excursion of the laser chirp given a probe waveform. This may also be calculated from the IQ phasor x, according to the formulas below:

$$BW = A {\sum }_{i = 0}^{N - 1} Δ θ ( i )$$

where BW is the total chirp bandwidth of the laser, A is a constant of proportionality that depends on the time delay difference of the MZI arms and the ADC sample rate and AO is the change in phase between two adjacent ADC samples. It may be calculated according to the formula below (or other methods that properly wrap the phase):

Δθ(n)∝angle(x(n)*x̅(n−1))

where x(n) is the complex representation of the data from the chirp feedback ADC at sample n, the overbar symbol represents complex conjugation, and the angle( ) operation calculates the angle of the complex phasor.

Given these feedback elements, a laser controller may monitor the wavelength feedback, the chirp loss, the chirp bandwidth, or combinations of these elements to evaluate the quality of an operating point. For the same actuator settings, a change in any of these feedback parameters indicates that the laser's response has changed and the laser may need an update to the operating point, a partial recalibration, or a complete recalibration. These feedback items may also be monitored continuously during operation to continuously update the laser's self-calibration.

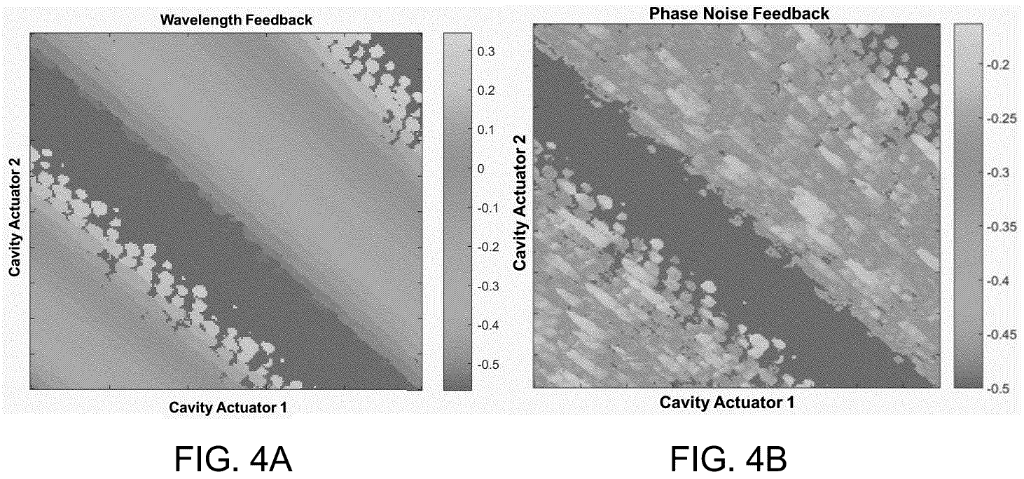

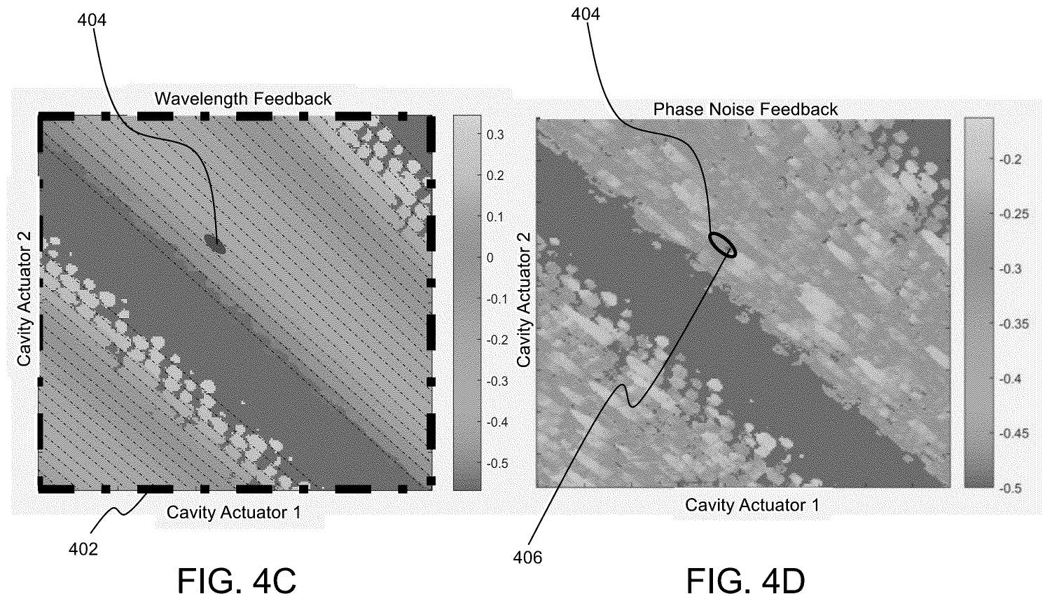

FIGS. 4A and 4B show plots of a prophetic example of wavelength feedback and phase noise feedback that is captured in-situ as two actuators inside a tunable laser cavity are adjusted. This in-situ monitoring allows the laser controller to select an operating point that is within a tolerance range of a wavelength goal that reduces the amount of phase noise feedback.

FIGS. 4C and 4D show plots of a prophetic example of how in-situ monitoring can be used to calibrate a wavelength tunable laser. In this example, a (possibly sparse) search is first performed on boundaries 402 of the actuator space, while simultaneously recording the laser's output wavelength. After the sparse search, a model of the wavelength of the laser as a function of the actuator inputs is formed to predict the wavelength of the laser based on the actuator values. Once that model is formed, the laser controller tunes the actuators to the predicted wavelength and performs a local search in a search area 404 around the predicted operating point. By monitoring the wavelength (as shown in FIG. 4C) and phase change (as shown in FIG. 4D), as well as information about the actuators, the laser controller can collect the wavelength, phase noise, bandwidth, and power of the laser around the predicted operating point. The laser controller then picks an operating point 406 that optimizes a desired parameter (for instance, output power or phase noise) that also satisfies any additional constraints such as wavelength or chirp bandwidth.

While the laser is operating, the laser controller may continue to monitor the wavelength feedback and phase change sensors to stabilize or further optimize the operating point. One approach to perform this is to continuously monitor feedback such as phase noise, bandwidth, wavelength feedback, or output power and trigger a re-calibration event if those parameters are sufficiently different from the initial or desired operating point. Another approach is to intentionally inject perturbations into the laser actuators while simultaneously monitoring the laser's phase noise, bandwidth, wavelength, or power response. The laser and the laser controller may be configured to adjust the operating points or actuator models based on the measured response.

This section relates to generating frequency chirps in lasers. Frequency chirps in lasers can be generated by creating a time-varying change in the optical path length of the laser cavity. Changing the optical path length of a laser cavity causes the frequency of the cavity modes to change, changing the output frequency of the laser. For example, in diode lasers, the optical path length can be changed by injecting a time-varying current into the gain medium. This causes a change in the effective index due to a change in carrier density and a change in temperature in the gain medium (e.g., a quantum well). Other approaches may be taken, such as the addition of a tunable element inside the cavity (like a phase shifter, ring, or grating). Many of these tuning elements have an unintended coupling between output power and optical path length (e.g., based on changes caused by the tuning element affecting cavity loss), causing the laser output power to modulate along with the frequency of the laser.

In some cases, it may be preferable that the change in frequency of the laser to a chirp actuator is linear and well-understood. When this is not the case, a feedback control loop may be used to correct for the uncertainties and/or non-linearities in the actuator.

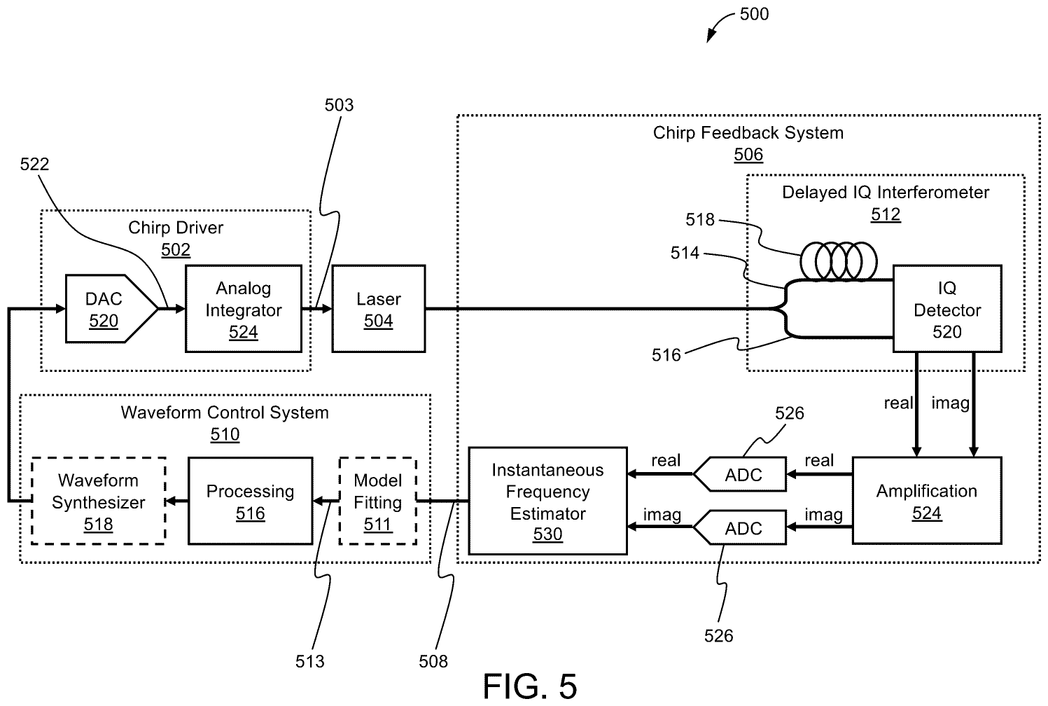

FIG. 5 shows a schematic diagram of an example laser system with feedback control 500. The laser system with feedback control 500 comprises a chirp driver 502 that outputs an actuation waveform 503 to a laser 504. The laser 504 sends at least a portion of its output to a chirp feedback system 506 that outputs an instantaneous chirp rate signal 508 that is sent to a waveform control system 510. The feedback control loop is closed by output from the waveform control system 510 being sent as input to the chirp driver 502. The waveform control system 510 comprises a model fitting element 511 that produces a fitted instantaneous chirp rate signal 513 that is sent to a processing element 516. An output of the processing element 516 is sent to a waveform synthesizer 518. A digital-to-analog converter (DAC) 520 receives an output from the waveform synthesizer 518 and generates a chirp rate command signal 522 that is sent to an analog integrator 524. The actuation waveform 503 is then generated as an output from the analog integrator 524 and sent to the laser 504. The chirp feedback system 506 comprises a delayed IQ interferometer 512 that receives light from the laser 504 and splits it into a first optical path 514 and a second optical path 516. The first optical path 514 comprises a delay element 518. The first optical path 514 and the second optical path 516 are connected to two input ports of an IQ detector 520, which produces an in-phase (also referred to as “real”) signal and a quadrature-phase signal (also referred to as “imag” or “imaginary”). An amplification element 524 amplifies both the in-phase signal and the quadrature-phase signal, while two ADCs 526 convert the two output signals of the amplification element 524 into two digital signals that are then sent to an instantaneous frequency estimator 530. The instantaneous frequency estimator 530 outputs the instantaneous chirp rate signal 508 that is sent to the waveform control system 510.

A fraction of output light from the laser can be tapped off and used to feed into a path-length delayed Mach Zehnder Interferometer that includes a photodiode or balanced detector but no IQ detector. This feedback without an IQ detector provides a real-valued output in the time domain with a frequency that is proportional to the chirp rate of the laser and the length of the delayed MZI. But, because the output is real-valued, the feedback circuit cannot differentiate between positive and negative frequencies in the frequency domain and cannot differentiate a change in amplitude from a phase change. To approximate the complex-valued output, additional processing can be performed, such as a Hilbert transform, Fourier Transform, or other processing, to convert the real-valued input to an instantaneous frequency estimate, which typically assumes that there is no amplitude modulation and no negative frequency content in the signal.

By using a delayed IQ interferometer that includes a delayed MZI and an IQ detector in the feedback path, as described in more detail herein, the laser controller is provided with a direct measurement of laser phase as a function of time. This may simplify the processing to determine instantaneous frequency, reduce processing latency, allow differentiation between positive and negative signals, and allow differentiation between amplitude variations and phase variations.

Given the in-phase (“I”) component of the chirp feedback and the quadrature-phase (“Q”) component of the chirp feedback, then the phase of the laser as a function of time is

$$ϕ ( t ) = {tan}^{- 1} \frac{Q}{I} .$$

The instantaneous frequency of the beat signal out of the delayed MZI is related to the derivative of the phase:

$$IF = \frac{1}{2 π} \frac{d ϕ ( t )}{dt} .$$

In a discrete-time sampled system, the instantaneous frequency (IF) can be estimated with a discrete time derivative:

$$IF = \frac{1}{2 π} \frac{1}{τ} Δ ϕ ( n ) ,$$

where τ is the sampling interval of the system and Δϕ(n)=ϕ(n)−(n)(n−1) and is wrapped to a boundary within−π and π. Alternately, Δϕ(n) may be calculated from the phasors according to Δθ(n)=angle (x(n)*x̅(n−1)), where x(n) is the phasor constructed from I and Q at sample n, and the overbar symbol represents complex conjugation.

In a system using a digital control loop, the chirp driver may include a digital to analog converter to generate the actuation waveform. The inclusion of an analog integrator after the DAC may reduce the bit depth required out of the DAC by changing the control waveform from a signal that is proportional to the frequency of the laser to a signal that is proportional to the chirp rate of the laser. For example, to generate a chirp-drive waveform with 10 kHz resolution over a total bandwidth of 1 GHz, a DAC with 17 bits of precision is required. In the case where an analog integrator follows the DAC, that same waveform can be represented by a constant voltage. The choice of bit depth for the DAC is then driven by the desired configurability of the chirp rate and any dynamic non-linearities in the chirp actuator that require the drive waveform to be non-constant. For lasers which simultaneously require narrow linewidths and large chirp excitations, this integral transformation may reduce the impact of a DAC bit on the output of the laser, reducing overall phase noise for the same bit depth. The inclusion of an analog integrator also means that the feedback signal from the instantaneous frequency estimator (which is proportional to the chirp rate of the laser) is in the same domain as the actuation output of the waveform synthesizer, simplifying the control loop.

In the case where a waveform is to be discovered so as to drive the chirp actuator using this feedback path, it may be important that the waveform chosen does not inject unintentional phase noise into the laser. When feedback from the instantaneous frequency estimator is used to derive the drive waveform, noise in the instantaneous frequency estimate will show up as noise in the drive waveform, degrading the linewidth of the laser. Because the instantaneous frequency calculation involves a derivative operation, the instantaneous frequency estimate accentuates noise at high frequencies and suppresses noise at low frequencies. By performing operations that smooth out high-frequency instantaneous frequency information, this noise injection may be suppressed.

High-frequency phase noise smoothing may be performed in several ways. For example, a causal lowpass filter can be used. However, this filtering may inject phase delays into the system that limit the rate at which real-time loops can be closed. In the case of systems that discover the drive waveform on a non-realtime or quasi-realtime fashion, non-causal zero-phase lowpass filters can be used, instead of such causal lowpass filters, so that the feedback signal exactly lines up in time with the desired drive waveform. Alternately, non-linear fitting can be used to match the instantaneous frequency feedback signal to a model of the non-linearity expected in the system's chirp actuator. For instance, a polynomial fit can be performed to the instantaneous frequency feedback signal, serving at least two purposes: (1) the non-linear fit smooths out and rejects high frequency noise in the feedback signal, and (2) the fit compresses the feedback signal into a lower-dimensional representation.

Both the instantaneous feedback waveform and the chirp actuation waveform may be represented as non-linear fits to polynomials or other models of the chirp actuator response. By doing so, a drive waveform optimizer may operate on the coefficients of the polynomials (e.g., summing coefficients associated with terms of the same order), rather than the time domain samples (reducing calculation complexity in the control loop), and the data storage requirements to describe the drive waveform are reduced. In applications where the laser must discover many chirp drive waveforms, this significantly reduces the memory requirements to describe the chirp actuation waveforms. (This includes applications such as wavelength tunable lasers, applications where many different laser chirp waveforms are required, or where drive actuation waveforms are adjusted depending on environmental factors.)

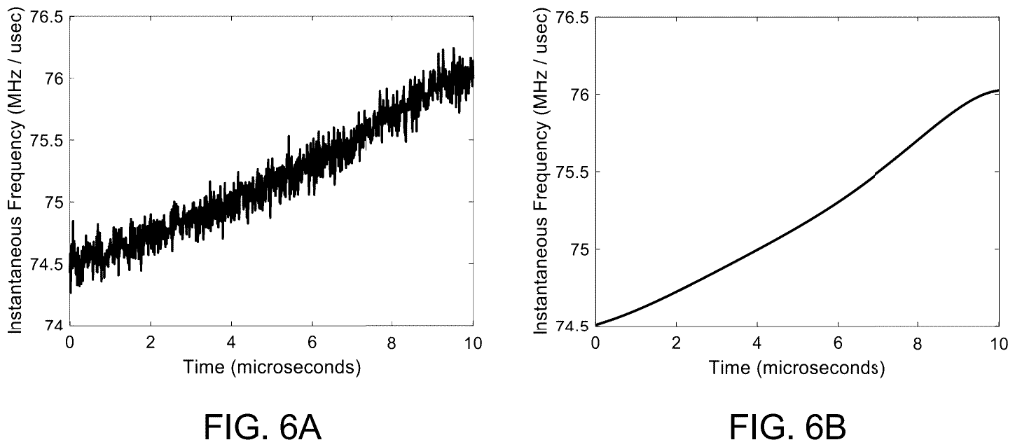

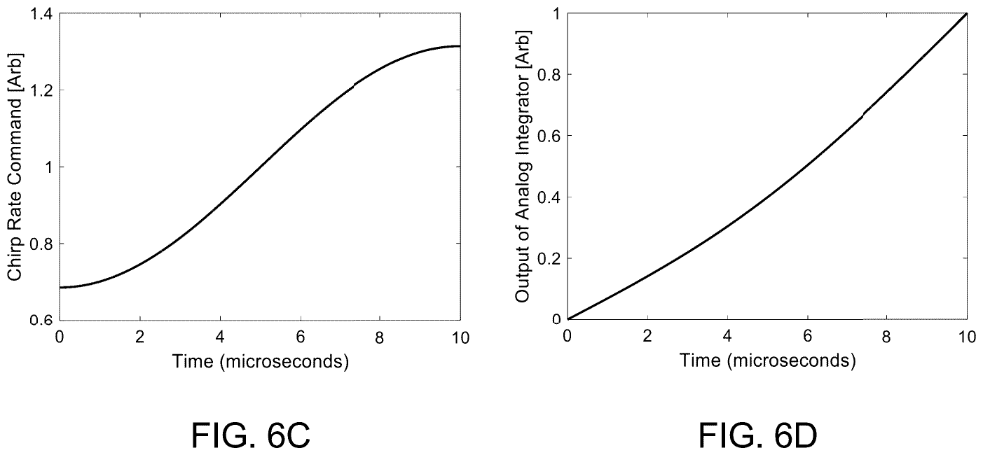

FIGS. 6A-D illustrate example signals described in FIG. 5 at various locations of the example laser system with feedback control 500.

FIG. 6A shows a prophetic plot of an example instantaneous chirp rate signal (e.g., 508 in FIG. 5) as a function of time, outputted from an instantaneous frequency estimator (e.g., 530 in FIG. 5).

FIG. 6B shows a prophetic plot of an example fitted instantaneous chirp rate signal (e.g., 513 in FIG. 5) as a function of time, outputted from a model fitting element (e.g., 511 in FIG. 5).

FIG. 6C shows a prophetic plot of an example chirp rate command signal (e.g., 522 in FIG. 5) as a function of time, outputted from a DAC (e.g., 520 in FIG. 5).

FIG. 6D shows a prophetic plot of an example actuation waveform (e.g., 503 in FIG. 5) as a function of time, outputted from an analog integrator (e.g., 524 in FIG. 5).

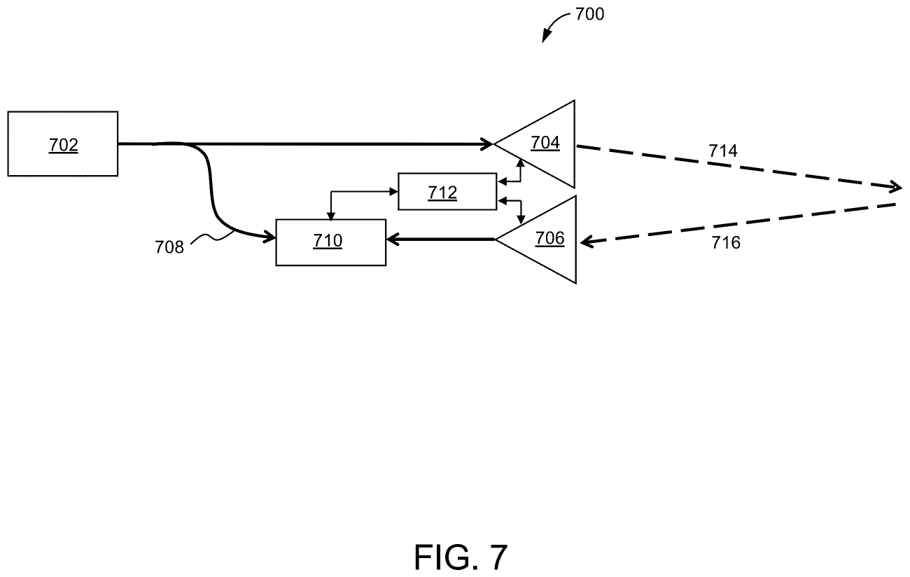

A laser system as described herein can be used in any of a variety of systems, including systems that use a single mode optical wave for various purposes, such as enabling a coherent receiver. FIG. 7 shows an example of a LiDAR system 700 with a coherent receiver. The LiDAR system 700 includes a laser system 702, a transmitter module 704 configured to transmit light provided by the laser system 702 (e.g., using an optical phased array) to a target region, and a receiver module 706 configured to receive light (e.g., using an optical phased array) and coherently mix the received light with light of a local oscillator (LO) 708, which can be derived the output of the laser system 702, in a coherent receiver 710 (e.g., an IQ receiver or a balanced detector). Mixing the received light with the LO can include ensuring the received light and the LO are in the same optical mode when they are spatially overlapped to optically interfere with each other. A control module 712 is configured to control various aspects of the transmitter module 704 and receiver module 706 and to estimate a distance to a target associated with a detection event based at least in part on a characteristic of the scattered light received by the receiver module 706, including a characteristic determined by the coherent mixing in the coherent receiver 710. The laser system 702 can provide a single mode continuous wave (CW) light signal that has a narrow linewidth and low phase noise, for example, sufficient to provide a temporal coherence length that is long enough to perform coherent detection over the time scales of interest. In some implementations, the laser system 702 is a frequency tunable laser system in which the frequency of the light provided can be swept to perform frequency modulated continuous wave (FMCW) LiDAR measurements. Optical phased arrays or other steering elements in the transmitter module 704 and the receiver module 706 can be configured to enable light provided at a transmitted angle 714 to be scattered by an object (not shown) and received at a reception angle 716.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An apparatus comprising:
an optical cavity formed on a substrate and configured to define a round-trip optical path,
an interface configured to position at least a portion of a gain medium to provide an active portion of the round-trip optical path over which the gain medium provides sufficient gain for the optical wave to propagate around the round-trip optical path in a single mode,
an output coupler configured to couple a portion of the optical wave out of the optical cavity from a passive portion of the round-trip optical path into a waveguide segment formed on the substrate,
one or more tap couplers each configured to divert less than 50% of optical power from the waveguide segment, and
one or more on-chip modules each configured to receive diverted optical power from at least one of the tap couplers and configured to provide information associated with a laser that comprises the optical cavity and the gain medium.

2. The apparatus of claim 1, further comprising a tuning element configured to tune a frequency of the optical wave.

3. The apparatus of claim 2, wherein at least one of the one or more on-chip modules comprises optoelectronic feedback circuitry configured to receive a first portion of the optical wave coupled out of the optical cavity and control the tuning element based at least in part on the received first portion of the optical wave, the optoelectronic feedback circuitry comprising:
a first optical splitter that splits the received first portion of the optical wave into two optical paths,
a first tree of optical paths with a second optical splitter that splits into two optical paths of substantially equal optical path lengths,
a second tree of optical paths with a third optical splitter that splits into two optical paths of substantially equal optical path lengths, where each optical path of the second tree is longer than each optical path of the first tree,
an optical phase shifter configured to impose an approximately quarter wavelength optical path length shift on one of the two optical paths of the first tree or one of the two optical paths of the second tree,
a first 2×2 optical coupler configured to combine a first of the two optical paths of the first tree and a first of the two optical paths of the second tree, and to provide two optical outputs to a first pair of photodetectors connected to provide a difference between their respective photocurrents as an in-phase electrical signal, and
a second 2×2 optical coupler configured to combine a second of the two optical paths of the first tree and a second of the two optical paths of the second tree, and to provide two optical outputs to a second pair of photodetectors connected to provide a difference between their respective photocurrents as a quadrature-phase electrical signal.

4. The apparatus of claim 3, wherein the optoelectronic feedback circuitry is configured to determine an estimate of an instantaneous frequency of the first portion of the optical wave based at least in part on the in-phase electrical signal and the quadrature-phase electrical signal.

5. The apparatus of claim 3, wherein the optoelectronic feedback circuitry is configured to apply an approximately linear chirp to the frequency of the first portion of the optical wave.

6. The apparatus of claim 5, wherein the approximately linear chirp is based at least in part on the in-phase electrical signal and the quadrature-phase electrical signal.

7. The apparatus of claim 5, wherein the optoelectronic feedback circuitry is configured to estimate a performance characteristic associated with the laser.

8. The apparatus of claim 7, wherein the performance characteristic comprises a chirp bandwidth of the laser during operation of the laser.

9. The apparatus of claim 3, wherein the optoelectronic feedback circuitry is configured to estimate a performance characteristic associated with the laser.

10. The apparatus of claim 9, wherein the performance characteristic is based at least in part on phase noise of the laser during operation of the laser.

11. The apparatus of claim 10, wherein the optoelectronic feedback circuitry is further configured to reduce low-frequency signals associated with the phase noise of the laser during operation of the laser.

12. The apparatus of claim 3, wherein the second tree includes an optical path length delay element on an optical path coupled to an input of the third optical splitter.

13. The apparatus of claim 3, wherein the second tree includes an optical path length delay element on each optical path coupled outputs of the third optical splitter.

14. The apparatus of claim 3, wherein at least one of the first optical splitter, the second optical splitter, the third optical splitter, the first 2×2 optical coupler, or the second 2×2 optical coupler comprises a directional coupler.

15. The apparatus of claim 3, wherein at least one of (1) the first pair of photodetectors or (2) the second pair of photodetectors are configured as a balanced detector.

16. The apparatus of claim 2, wherein a first on-chip module of the one or more on-chip modules comprises optoelectronic circuitry configured to generate, from at least a portion of the diverted optical power, a phase change signal encoding a change in phase of the portion of the diverted optical power as a function of time.

17. The apparatus of claim 2, wherein a first on-chip module of the one or more on-chip modules comprises optoelectronic circuitry configured to generate, from at least a portion of the diverted optical power, a wavelength signal encoding a wavelength of the portion of the diverted optical power as a function of time.

18. The apparatus of claim 17, wherein a second on-chip module of the one or more on-chip modules comprises optoelectronic circuitry configured to generate, from at least a portion of the diverted optical power, a phase change signal encoding a change in phase of the portion of the diverted optical power as a function of time.

19. The apparatus of claim 18, further comprising control circuitry configured to adjust the tuning element based at least in part on one or more of the wavelength signal or the phase change signal.

20. The apparatus of claim 19, wherein the optoelectronic circuitry of the first on-chip module comprises:
an optical splitter that splits a first portion of the optical wave coupled out of the optical cavity into at least two optical paths according to a splitting ratio that is dependent upon the wavelength of the portion of the diverted optical power, and
at least one photodetector coupled to each of at least two of the optical paths of the optical splitter.

21. The apparatus of claim 20, wherein the optical splitter is configured to split the first portion of the optical wave into exactly two optical paths.

22. The apparatus of claim 21, wherein the control circuitry is further configured to estimate the wavelength of the portion of the diverted optical power based at least in part on determining a difference between optical power in each of the optical paths of the optical splitter divided by a sum of the optical power in each of the optical paths of the optical splitter.

23. The apparatus of claim 20, wherein the optical splitter comprises a directional coupler.

24. The apparatus of claim 19, wherein the optoelectronic circuitry of the second on-chip module comprises a path-length mismatched Mach-Zehnder interferometer.

25. The apparatus of claim 24, wherein the path-length mismatched Mach-Zehnder interferometer comprises an In-phase and Quadrature-phase (IQ) detector at an output of the path-length mismatched Mach-Zehnder interferometer configured to provide an in-phase electrical signal and a quadrature-phase electrical signal.

26. The apparatus of claim 19, wherein the control circuitry is configured to estimate a magnitude of a performance characteristic associated with the laser based at least in part on the phase change signal.

27. The apparatus of claim 26, wherein estimating the performance characteristic comprises calculating a magnitude of a sum of a plurality of phasors at each of a plurality of estimates of instantaneous frequency of the optical wave at different times.

28. The apparatus of claim 26, wherein estimating the performance characteristic comprises calculating a Fourier transform of the phase change signal and determining magnitudes of one or more tones in the Fourier transform.

29. The apparatus of claim 19, further comprising: a chirp actuator configured to apply a chirp to a frequency of the optical wave, and a waveform generator configured to drive the chirp actuator according to a waveform generated by the waveform generator.

30. The apparatus of claim 29, wherein the control circuitry is further configured to provide a phase control signal based at least in part on the phase change signal to the waveform generator throughout at least a portion of a duration of the generation of the waveform.

31. The apparatus of claim 30, wherein the control circuitry is configured to estimate a loss due to phase noise based at least in part on the phase change signal.

32. The apparatus of claim 31, wherein the control circuitry is configured to remove low-frequency phase noise from a calculation of phase noise for the estimated loss due to phase noise.

33. The apparatus of claim 30, wherein the control circuitry is configured to estimate a total bandwidth excursion of the laser during at least a portion of a duration of the generation of the waveform.

34. The apparatus of claim 19, wherein control circuitry is configured to use one or both of the wavelength signal or the phase change signal to calibrate the laser.

35. The apparatus of claim 19, wherein control circuitry is configured to use one or both of the wavelength signal or the phase change signal to update an existing calibration of the laser.

36. The apparatus of claim 19, wherein control circuitry is configured to use one or both of the wavelength signal or the phase change signal to optimize a local operating point of the laser.

37. The apparatus of claim 19, wherein control circuitry is configured to use one or both of the wavelength signal and the phase change signal to identify a change in performance of the laser while the laser is operating.

38. The apparatus of claim 2, further comprising a coherent receiver configured to spatially overlap (1) a received optical wave derived from the optical wave propagating around the round-trip optical path in the single mode with (2) a local oscillator optical wave having a substantially identical mode as the received optical wave.

39. The apparatus of claim 1, wherein the gain medium comprises a semiconductor laser diode medium.

40. The apparatus of claim 1, wherein the substrate comprises a silicon substrate of a silicon photonic integrated circuit, and the one or more on-chip modules are formed on the silicon photonic integrated circuit.

41. The apparatus of claim 40, wherein the gain medium is formed on a gain medium substrate other than the silicon substrate.

42. The apparatus of claim 41, wherein the gain medium substrate comprises a III-V semiconductor material.

43. A method for calibrating a wavelength of an optical wave output from a laser, the method comprising:
characterizing a response of the wavelength to one or more actuators in the laser,
storing information associated with a model of the characterized response,
operating the laser at one or more operating points by modifying at least one of the one or more actuators in the laser,
for at least a first of the operating points, measuring at least one of: a linewidth, a chirp bandwidth, or the wavelength around the first of the operating points, and
performing a fine-adjustment of at least one of the actuators based at least in part on one or more of the measurements.

44. The method of claim 43, wherein characterizing the response comprises searching for two or more sets of parameters associated with the actuators that generate a substantially similar wavelength of the laser.

45. The method of claim 43, wherein characterizing the response comprises processing an electronic feedback signal from a circuit on a photonic integrated circuit that comprises the laser.

46. The method of claim 43, further comprising measuring, for at least one of the operating points, an output power of the optical wave.

47. A method for managing an operating point associated with a laser, the method comprising:
monitoring a wavelength of an optical wave output from the laser during operation over a duration of time,
monitoring a change in phase of the optical wave during operation over the duration of time, and
modifying one or more actuators associated with the laser in response to at least one of (1) the monitored wavelength or (2) the monitored change in phase.

48. The method of claim 47, further comprising calculating phase noise based on the monitored change in phase.

49. The method of claim 47, wherein monitoring the change in phase is performed while the laser is performing a frequency chirp.

50. The method of claim 49, further comprising monitoring a bandwidth associated with the frequency chirp.

51. The method of claim 47, further comprising monitoring an output power of the optical wave over the duration of time.

52. The method of claim 47, further comprising modifying at least one of the actuators to result in a predetermined wavelength of the optical wave.

53. The method of claim 52, wherein the operating point is constrained by at least one of a determined phase noise or a determined chirp bandwidth.

54. The method of claim 47, wherein the operating point is constrained by a determined phase noise.

55. The method of claim 54, wherein the operating point is constrained by at least one of a determined wavelength or a determined chirp bandwidth.

56. The method of claim 47, the operating point is constrained by a determined chirp bandwidth.

57. The method of claim 56, wherein the operating point is constrained by at least one of a determined wavelength or a determined phase noise.

58. The method of claim 47, wherein the operating point is constrained by a determined output power.

59. The method of claim 58, wherein the operating point is constrained by a predetermined wavelength, determined phase noise, or determined chirp bandwidth.

60. The method of claim 59, wherein the operating point is constrained by a predetermined phase noise.

61. A method for managing a laser, the method comprising:
receiving, over a duration of time, one or more sets of electrical signals comprising an in-phase electrical signal and a quadrature-phase electrical signal from one or more photodetectors coupled to an interferometer that receives a portion of an optical wave output from the laser,
generating digital representations of the in-phase electrical signal and the quadrature-phase electrical signal, and
controlling a frequency of the optical wave based at least in part on at least one instantaneous frequency estimate calculated from the digital representations.

62. The method of claim 61, further comprising calculating the instantaneous frequency estimate based at least in part on estimating a derivative of a phase calculated from the digital representations.

63. The method of claim 62, further comprising calculating the derivative of the phase based at least in part on a phase difference between adjacent samples of the digital representations.

64. The method of claim 63, wherein calculating the phase difference comprises calculating respective phases each proportional to an arctangent of a ratio of the quadrature-phase electrical signal to the in-phase electrical signal at each of a plurality of samples of the digital representations, and calculating differences between respective phases.

65. The method of claim 64, wherein estimating the instantaneous frequency comprises wrapping the difference between the respective phases to a value within −pi to pi.

66. The method of claim 63, wherein calculating the phase difference comprises calculating an arctangent of a product of a complex-valued signal comprising the digital representations at a first sample and a complex conjugate of the complex-valued signal at a second sample adjacent to the first sample.

67. The method of claim 61, further comprising compressing instantaneous frequency estimate in storage size.

68. The method of claim 61, further comprising filtering the instantaneous frequency estimate.

69. The method of claim 68, wherein the filtering is configured to use a zero-phase filter or a lowpass filter.

70. The method of claim 61, further comprising representing the instantaneous frequency estimate as a model-based fit of the instantaneous frequency estimate.

71. The method of claim 70, wherein the model-based fit comprises a polynomial fit.

72. The method of claim 61, wherein controlling the frequency of the optical wave comprises controlling a rate of change of the frequency.

73. The method of claim 72, wherein controlling the rate of change of the frequency comprises generating a substantially linear rate of change of the frequency over each of a plurality of time periods.
